(19) United States
(12) Patent Application Publication
(10) Pub. No.: US 2019/0258071 A1
(43) Pub. Date: Aug. 22, 2019

(54) THREE-DIMENSIONAL DISPLAY PANEL AND DISPLAY DEVICE

(71) Applicant: BOE TECHNOLOGY GROUP CO., LTD., Beijing (CN)

(72) Inventors: Xue Dong, Beijing (CN); Jinye Zhu, Beijing (CN); Wenqing Zhao, Beijing (CN); Xiaochuan Chen, Beijing (CN)

(73) Assignee: BOE TECHNOLOGY GROUP CO., LTD., Beijing (CN)

(21) Appl. No.: 16/345,846

(22) PCT Filed: Oct. 17, 2018
(86) PCT No.: PCT/CN2018/110606

§ 371 Date: Apr. 29, 2019

(30) Foreign Application Priority Data
Oct. 17, 2017 (CN) 201710965088.4

(51) Int. Cl. G02B 27/22; H01L 27/32; G02F 1/1335; H01L 51/52

(52) U.S. Cl. CPC G02B 27/2214; H01L 27/3213; H01L 27/3218; G02F 1/133526; G02F 2201/52; H01L 51/5275; H01L 27/3246; H01L 27/3283; G02F 1/133512

(57) ABSTRACT

The present disclosure generally relates to display technologies, and in particular, to three-dimensional display technologies. A three-dimensional display panel includes a plurality of pixel units arranged in an array. Each pixel unit includes at least two subpixels which are spaced apart from each other, and at least one light controller on the plurality of pixel units. The at least one light controller is configured to control directions of lights emitted from the plurality of pixel units.

### CROSS-REFERENCE TO RELATED APPLICATIONS

This application claims the benefit of the filing date of Chinese Patent Application No. 201710965088.4 filed on Oct. 17, 2017, the entire disclosure of which is hereby incorporated by reference.

### TECHNICAL FIELD

The present disclosure relates generally to display technology, and in particular to three-dimensional display technology.

### BACKGROUND

Light field display technology generates an image by capturing information such as directions and positions of lights in a light field emanating from an object, and then reconstructing an image of the object based on the captured information. Light field display technology is able to create images that are more realistic than conventional two-dimensional display techniques.

### BRIEF SUMMARY

One embodiment of the present disclosure is a three-dimensional display panel. The three-dimensional display panel may comprise a plurality of pixel units arranged in an array, each pixel unit comprising at least two subpixels which are spaced apart from each other, and at least one light controller on the plurality of pixel units, the at least one light controller being configured to control directions of lights emitted from the plurality of pixel units.

In at least some embodiments, each pixel unit may comprise three or four subpixels that are spaced apart.

In at least some embodiments, each pixel unit may comprise four subpixels that are arranged to show a diamond shape.

In at least some embodiments, a distance between each pair of adjacent subpixels may be the same.

In at least some embodiments, the three-dimensional display panel may comprise a plurality of light controllers. A light controller may be provided on each subpixel of each pixel unit. Each light controller may be configured to control a direction of light emitted through each subpixel, so that lights emitted through different subpixels of the pixel unit are directed to follow different optical paths.

In at least some embodiments, the three-dimensional display panel may further comprise a plurality of light controllers arranged in an array. A light controller may be provided on each pixel unit and may cover the at least two subpixels of the pixel unit. The light controller may be configured to direct lights passing through different regions of the lens to follow different optical paths. In at least some embodiments, each light controller may be a free-form lens.

In at least some embodiments, the three-dimensional display panel may further comprise a plurality of light controllers arranged in an array. A light controller may be provided on each pixel unit and may cover the at least two subpixels of the pixel unit. Each light controller may be configured to direct lights emitted through different subpixels of the pixel unit to follow the same optical path.

In at least some embodiments, the three-dimensional display panel may comprise a plurality of light controllers. Each light controller may cover a group of adjacent pixel units, and may be configured to direct lights emitted by different pixel units in the group of adjacent pixel units lo follow different optical paths.

In at least some embodiments, each light controller may be a free-form lens.

In at least some embodiments, the three-dimensional display panel may be a liquid crystal three-dimensional display panel. The three-dimensional display panel may further comprises a black matrix on the plurality of pixel units. The black matrix may comprise a plurality of openings that correspond to the at least two subpixels of each of the plurality of pixel units.

In at least some embodiments, the three-dimensional display panel may be an organic light-emitting diode three-dimensional display panel. The three-dimensional display panel may further comprise a pixel defining layer on the plurality of pixel units. The pixel defining layer may comprise a plurality of openings that correspond to the at least two subpixels of each of the plurality of pixel units.

Another embodiment of the present disclosure is a display device. The display device may comprise a three-dimensional display panel as described above.

### BRIEF DESCRIPTION OF THE DRAWINGS

The subject matter that is regarded as the invention is particularly pointed out and distinctly chimed in the claims at the conclusion of the specification. The foregoing and other objects, features, and advantages of the present disclosure are apparent from the following detailed description taken in conjunction with the accompanying drawings in which:

FIG. 1 shows a schematic diagram of a three-dimensional display panel according to an embodiment of the present disclosure;

FIG. 2 shows a schematic diagram of a three-dimensional display panel according to another embodiment of the present disclosure;

FIG. 3A shows a schematic diagram illustrating an arrangement of a light controller and a pixel unit in an embodiment of the present disclosure;

FIG. 3B shows a schematic diagram illustrating an arrangement of a light controller and a pixel unit in another embodiment of the present disclosure;

FIG. 4A shows a schematic diagram illustrating an arrangement of a light controller and a pixel unit in another embodiment of the present disclosure; and

FIG. 4B shows a schematic diagram illustrating an arrangement of a light controller and a pixel unit in an embodiment of the present disclosure;

The various features of the drawings are not to scale as the illustrations are for clarity in facilitating one skilled in the art in understanding the invention in conjunction with the detailed description.

### DETAILED DESCRIPTION

Next, the embodiments of the present disclosure will be described clearly and concretely in conjunction with the accompanying drawings, which are described briefly above. The subject matter of the present disclosure is described with specificity to meet statutory requirements. However, the description itself is not intended to limit the scope of this disclosure. Rather, the inventors contemplate that the claimed subject matter might also be embodied in other ways, to include different steps or elements similar to the ones described in this document, in conjunction with other present or future technologies.

While the present technology has been described in connection with the embodiments of the various figures, it is to be understood that other similar embodiments may be used or modifications and additions may be made to the described embodiments for performing the same function of the present technology without deviating therefrom. Therefore, the present technology should not be limited to any single embodiment, but rather should be construed in breadth and scope in accordance with the appended claims. In addition, all other embodiments obtained by one of ordinary skill in the art based on embodiments described in this document are considered to be within the scope of this disclosure.

Light field display technology is generally one of two types: light field stereoscopic display or microlens array display. In microlens array display, a microlens array is placed in front of the display to create a light field. An image entering the display device is split by the lenslets in the microlens array into dozens of sets of pixels having different depths, and the sets of pixels collectively reconstruct and display the image using the image data projected by the subpixels on the microlens array. Content of the image having different depths are produced by the corresponding pixels. When viewing displays by pixels based on image data from different subpixels, the user may perceive different display as having different depths, which allows the user to experience a realistic three-dimensional display.

Existing three-dimensional light field display technologies, whether they adopt the microlens array technology or someone, may be susceptible to interferences that may arise between the light spots of adjacent pixels. This interference may become magnified by the display device, thus causing deteriorations in the display effects and in the user's viewing experience.

The present disclosure provides a three-dimensional display panel and a display device that are capable of addressing the problems identified above.

A pixel unit comprises at least two subpixels that are spaced apart from each other, which can reduce the size of the light spot that is produced by the pixel unit. More particularly, even when the pixel units in embodiments according to the present disclosure have the same or similar surface area as a pixel unit used in conventional techniques, the pixel unit according to the present disclosure produces a much smaller light spot than the conventional pixel unit. This can in turn reduce interferences between light spots of pixel units, and improve display quality and a user's viewing experience.

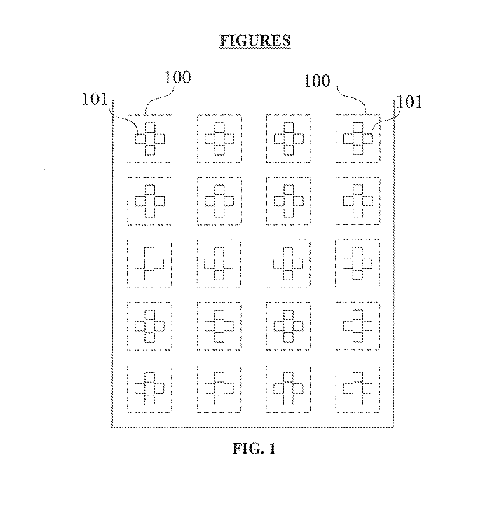

FIG. 1 shows a schematic diagram of a three-dimensional display panel according to an embodiment of the present disclosure.

The three-dimensional display panel comprises a plurality of pixel units 100. Each pixel unit 100 comprises at least two subpixels 101 that are spaced apart from each other. In some embodiments, the distance between adjacent subpixels 101 in a pixel unit 100 is the same. Each subpixel may be configured to have a rectangular shape, a circular shape, or other standard geometrical shape. This configuration can reduce crosstalk and satisfy the requirement for multi-angle viewability, while at the same time, simplifying design and construction.

In a three-dimensional display panel according to the present disclosure, a pixel unit comprises at least two subpixels that are spaced apart from each other, which can reduce the size of the light spot that is produced by the pixel unit. More particularly, even when the pixel units in embodiments according to the present disclosure have the same or similar surface area as a pixel unit used in conventional techniques, the pixel unit according to the present disclosure produces a much smaller light spot than the conventional pixel unit. This can in turn reduce interferences between light spots of pixel units, and improve display quality and a user's viewing experience.

In some embodiments, each pixel unit comprises three to four subpixels that are spaced apart from each other. Light is emitted through each display area, so that each pixel unit emits three to four beams alights. This configuration can reduce crosstalk without complicating the manufacturing process.

In some embodiments, each pixel unit comprises four subpixels that are spaced apart from each other. The four display areas may be arranged to show a diamond shape, that is, a continuous line through the centers of the four subpixels defines a diamond shape. This configuration can reduce crosstalk, while facilitating design and construction.

A pixel unit 100 may be configured to emit a desirable color, including, for example, red, green, blue, and white. The display region corresponding to each pixel unit 100 is defined by the subpixels 101.

The three-dimensional display panel may be a liquid crystal display (LCD) panel or an organic light-emitting diode (OLED) display panel.

In embodiments where the three-dimensional display panel is a LCD display panel, the three-dimensional display panel comprises a black matrix. The black matrix is divided into a plurality of areas. The number of areas into which the black matrix is divided corresponds to number of display areas on the pixel unit. Each area of the black matrix comprises at least two openings, each opening corresponding to one of the subpixels on the pixel unit. An opening in the black matrix defines a portion of the black matrix that exposes or substantially exposes an underlying layer, for example, the subpixel. During fabrication of the LCD three-dimensional display panel, each pixel unit may be patterned according to the pattern of the black matrix, so that each pixel unit comprises at least two subpixels that are spaced apart and each of the subpixel corresponds to one of the openings in the black matrix.

In embodiments where the three-dimensional display panel is an OLED display panel, the three-dimensional display panel comprises a pixel defining layer. The pixel defining layer is divided into a plurality of regions corresponding to the number of subpixels in the pixel unit. Each region of the pixel defining layer comprises at least two openings, each opening corresponding to one of the subpixels of the pixel unit. An opening in the pixel defining layer defines a portion of the pixel defining layer that exposes or substantially exposes an underlying layer, for example, the subpixel. During fabrication of the OLED three-dimensional display panel, each pixel unit may be patterned according to the pattern of the pixel defining layer, so that each pixel unit comprises at least two subpixels that are spaced apart and each of the subpixels corresponds to one of the openings in the pixel defining layer.

Patterning a pixel unit according to the pattern of the black matrix or the pixel defining layer simplifies the display panel fabrication process. It is understood that a pixel unit may also be patterned according to other appropriate means to a person of ordinary skill in the art, including, for example, using a shielding layer or other layers of the display panel.

The subpixels in a pixel unit are configured to have the same or substantially the same shape and area as each other. Each subpixel is positioned to correspond to an opening in the black matrix or the pixel defining layer. This configuration makes it possible to produce an uniform display.

The three-dimensional display panel according to the present disclosure can be used in light field display techniques, including, for example, in light field stereoscopic display, microlens way display, or other types of light field displays. In embodiments where the three-dimensional display panel is incorporated into a microlens array display, each subpixel recording particular depth information comprises at least two display areas that are spaced apart.

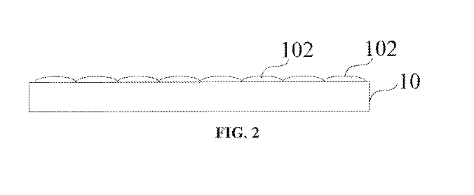

In addition, in embodiments where the three-dimensional display panel is incorporated into a microlens array display, multiple viewing angles may be effected on the three-dimensional display panel. FIG. 2 shows a schematic diagram of a three-dimensional display panel according to another embodiment of the present disclosure. The three-dimensional display panel comprises a display panel 10 and a plurality of light controllers 102 on the display panel. The light controller 102 is configured to control the direction of light emitted by a subpixel 101.

The light controller 102 may comprise a microlens, a microprism, a free-form lens, or a grating. it is understood that the light controller 102 may comprise any appropriate optical element known to a person of ordinary skill in the art, so long as the function of controlling light directionality is enabled. In some embodiments, the light controller 102 may comprise a circular microlens having a standard curvature. In some embodiments, the light controller 102 may comprise a free-form lens having irregular curvature.

At least one light controller 102 is provided on each pixel unit 100. In some embodiments, one light controller 102 is provided on each subpixel 101 of a pixel unit 100. In some embodiments, one light controller 102 is provided on a group of pixel units 100. A plurality of light controllers 102 may be arranged to form a light controller array.

In some embodiments, each pixel unit is configured to emit a light through each subpixel. Since each pixel unit comprises at least two subpixels, each pixel unit is therefore configured to emit at least two beams of light. A light controller 102 is configured to control the at least two beams of light to follow different optical paths to different viewing positions. A viewing position is a position at which a complete three-dimensional image displayed by the three-dimensional display panel can be viewed in front of the three-dimensional display panel. A viewing position is a point of convergence of lights emitted by the pixel units to generate different pixels in the image being displayed. Each subpixel of the pixel unit corresponds to a viewing position. Lights emitted by any given pair of pixel units are controlled by the corresponding light controller (or light controllers) to follow the same set of optical paths. For example, if lights emitted by a first pixel unit is controlled to follow four optical paths A, B, C, and D, then lights emitted by a second pixel unit is also controlled to follow the same tour optical paths A, B, C, and D, and lights emitted by each of the other pixel units are also controlled to follow the same four optical paths A, B, C, and D. As a result, a viewer is able to view a display on the three-dimensional display panel from four different viewing angles corresponding to the optical paths A, B, C, and D.

In some embodiments, lights emitted by a group of pixel units are controlled to follow different optical paths to different viewing positions. Each group of pixel units comprises at least two pixel units of the same color, the at least two pixel units corresponding to the same pixel in the image to be displayed by the three-dimensional display panel. Light emitted by each pixel unit in a group of pixel units is directed toward a different viewing position. Lights emitted by any given pair of groups of pixel units are controlled by the corresponding light controller (or light controllers) to follow the same set of optical paths to the same set of viewing positions.

In other words, there are two modes of configuring a three-dimensional display panel according to the present disclosure for viewing from multiple viewing angles. In the first mode, lights emitted by each pixel unit are controlled to follow different optical paths to different viewing positions. In the second mode, lights emitted by a group of pixel units are controlled to follow different optical paths to different viewing positions. A viewing position is a position at which a complete three-dimensional image displayed by the three-dimensional display panel can be viewed in front of the three-dimensional display panel. A viewing position is a point of convergence of lights emitted by the pixel units to generate different pixels in the image being displayed. Controlling the viewing position of light emitted by a pixel unit necessarily controls the optical path of light emitted by the pixel unit. Each optical path necessarily passes through the corresponding viewing position.

The first mode for achieving multiple viewing angles may be effected in the manner described below.

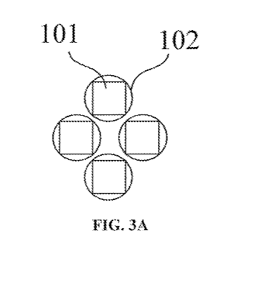

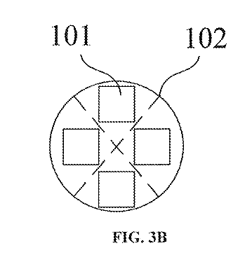

FIG. 3A shows a schematic diagram illustrating an arrangement of a light controller and a pixel unit in an embodiment of the present disclosure.

As shown in FIG. 3A, in each pixel unit 100, a light controller 102 is provided on each subpixel 101, through which subpixel light is emitted. In other words, in the embodiment illustrated in FIG. 3A, the light controllers 102 are arranged to correspond to the subpixels 101, and each light controller 102 is configured to control the direction of the light emitted through the corresponding subpixel 101. A group of light controllers 102 controls lights emitted through the at least two subpixels 101 of the pixel unit 100 to follow different optical paths to different viewing positions, so as to enable viewing from multiple angles.

In the embodiment illustrated in FIG. 3A, the light controller 102 may comprise a microlens, a microprism, a free-form lens, or a grating.

FIG. 3B shows a schematic diagram illustrating an arrangement of a light controller and a pixel unit in another embodiment of the present disclosure.

As shown in FIG. 3B, in each pixel unit 100, a single light controller 102 is provided on the at least two subpixels 101. In other words, the light controller 102 is arranged to correspond to the pixel unit 100. The light controller 102 is configured to control the directions of lights emitted through the at least two subpixels 101, so that the emitted lights follow different optical paths to different viewing positions, thus achieving multi-angle viewability.

Lights emitted through the at least two subpixels 101 in the pixel unit 100 pass through different regions of the light controller 102. Refraction as lights pass through different regions of the light controller 102 causes those lights, which travel in the same direction initially, to propagate along follow different optical paths toward different viewing positions.

In the embodiment illustrated in FIG. 3B, the light controller 102 may comprise a microlens, a microprism, a free-form lens, or a grating. In some embodiments, the light controller is a microlens. Lights emitted through the four subpixels 101 pass through four different regions of the microlens. The microlens is divided into four regions in the circumferential direction, for example, as shown in FIG. 3B. Lights passing through the four regions of the microlens are subject to different refractions, and as a result, are bent in different directions.

In addition, lights emitted by pixel units 100 at different positions of the display panel may pass through microlenses that are centered at different positions on the display panel. For example, the microlens through which lights emitted by a pixel unit 100 located toward the center of the display panel will also have a center that is located toward the center of the display panel. On the other hand, the microlens through which lights emitted by a pixel unit 100 located on the periphery of the display panel will have a center located away from the center of the display panel.

The second mode for achieving multiple viewing angles may effected in the manner described below.

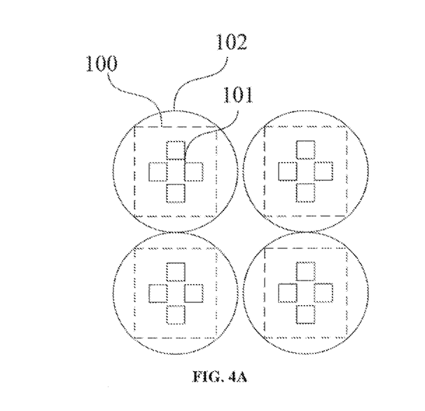

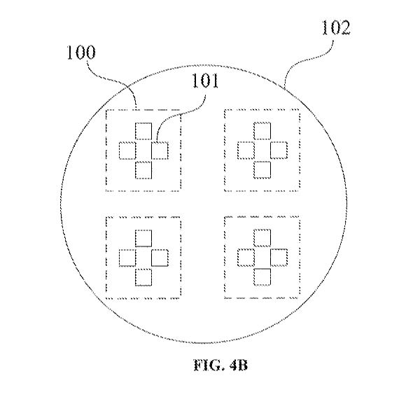

FIG. 4A shows a schematic diagram illustrating an arrangement of a light controller and a pixel unit in another embodiment of the present disclosure.

As shown in FIG. 4A, a light controller array comprises a plurality alight controllers 102 corresponding to a plurality of pixel units 100. Each light controller 102 is provided on a pixel unit 100 that comprises at least two subpixels 101. The light controller 102 is configured to control the lights emitted through the subpixels 101, so that lights emitted through different subpixels 101 of the same pixel unit 100 are propagated along the, same optical path toward the same viewing position. In other words, the light controller 102 is arranged to correspond to a pixel unit 100. The light controller 102 is configured to direct lights emitted through different subpixels 101 of the same pixel unit 100 to follow the same optical path toward the same viewing position, and lights emitted by different pixel units 100 to follow different optical paths toward different viewing positions. In this way, the three-dimensional display panel is imparted with multi-angle viewability.

Each pixel unit 100 may be arranged in the center or substantially in the center of a light controller 102. This arrangement can ensure that lights emitted through different subpixels 101 of the same pixel unit 100 are refracted in the same direction, and are propagated along the same optical path.

In the embodiment illustrated in FIG. 4A, the light controller 102 may comprise a microlens, a microprism, a free-form lens, or a grating.

FIG. 4B shows a schematic diagram illustrating an arrangement of a light controller and a pixel unit in an embodiment of the present disclosure

As shown in FIG. 4B, a single light controller 102 controls a plurality of pixel units 100. Lights emitted by different pixel units 100 of the plurality of pixel units 100 are directed by the light controller 102 to travel along different optical paths toward different viewing positions. In other words, the light controller 102 is arranged to correspond to the pixel unit 100, and is configured to direct lights emitted by different pixel units 100 to travel along different optical paths. Lights emitted through different subpixels 101 of the same pixel unit 100 are control to follow the same optical path.

Lights emitted by different pixel units 100 pass through different regions of the light controller 102. Refraction as lights pass through different regions of the light controller 102 causes those lights, which travel in the same direction initially, to propagate along follow different optical paths toward different viewing positions.

In the embodiment illustrated in FIG. 4B, the light controller 102 may comprise a microlens, a microprism, a free-form lens, or a grating. In some embodiments, the light controller is a free-form lens. Lights emitted through the four pixel units 100 pass through four different regions of the free-term lens. The free-form lens is divided into four regions in the circumferential direction, for example, as shown in FIG. 4B. The four regions of the free-form lens have different curvatures, and therefore different refractive properties. As a result, lights passing alma the four regions of the free-form lens are subject to different refractions, and are refracted in different directions.

The first mode, for example, as shown in FIGS. 3A and 3B, imparts the three-dimensional display panel with multi-angle viewability, without loss of resolution. However, the fabrication of the suitable light controllers may be more complex. The second mode, for example, as shown in FIGS. 4A and 4B, likewise imparts the three-dimensional display panel with multi-angle viewability. The second mode utilizes a plurality of pixel units of the same color to display a pixel in the image being displayed on the display panel. As compared to an embodiment where the pixel units of the same color are applied to display different pixels in the image, the second mode may reduce the resolution. However, the fabrication of light controllers suitable for use in the second mode may be simpler.

The three-dimensional display panel according to the present disclosure is designed to be capable of providing multi-angle viewing. Pixel units corresponding to pixels displaying different depths in the three-dimensional image emit multiple lights in different directions, so that a viewer is able to view the three-dimensional image front different angles.

In some embodiments, each pixel unit comprises three to four subpixels that are spaced apart. Light is emitted through each subpixel, so that each pixel unit emits three to four beams of lights. This configuration can reduce crosstalk without complicating the manufacturing process.

In some embodiments, each pixel unit comprises four subpixels that are spaced apart. The four subpixels may be arranged to show a diamond shape, that is, a continuous line through the centers of the four subpixels defines a diamond shape. This configuration can reduce crosstalk, while facilitating design and construction.

Each subpixel may be configured to have a rectangular shape, a circular shape, or other standard geometrical shape. This configuration can reduce crosstalk and satisfy the requirement for multi-angle viewability, while at the same time, simplifying design and construction.

The present disclosure also provides a display device. The display device comprises a three-dimensional display panel as described above. The three-dimensional display panel according to the present disclosure may be integrated into any display device, including, but not limited to, a mobile phone, a tablet, a television, a computer, a display, a notebook computer, a digital photo frame, a navigation system, and any other products or components that provide a display function.

A pixel unit comprises at least two subpixels, which can reduce the size of the light spot that is produced by the pixel unit. More particularly, even when the pixel units in embodiments according to the present disclosure have the same or similar surface area as a pixel unit used in conventional techniques, the pixel unit according to the present disclosure produces a much smaller light spot than the conventional pixel unit. This can in turn reduce interferences between light spots of pixel units, and improve display quality and a user's viewing experience.

It should be appreciated that changes could be made to the embodiments described above without departing from the inventive concepts thereof. It should be understood, therefore, that this invention is not limited to the particular embodiments disclosed, but it is intended to cover modifications within the spirit and scope of the present invention as defined by the appended claims.

1. A three-dimensional display panel, comprising:
a plurality of pixel units arranged in an array, each pixel unit comprising at least two subpixels which are spaced apart from each other, and
at least one light controller on the plurality of pixel units, the at least one light controller being configured to control directions of lights emitted from the plurality of pixel units.

2. The three-dimensional display panel according to claim 1, wherein each pixel unit comprises three or four subpixels that are spaced apart.

3. The three-dimensional display panel according to claim 1, wherein each pixel unit comprises four subpixels that are arranged to show a diamond shape.

4. The three-dimensional display panel according to claim 2, wherein a distance between each pair of adjacent subpixels is the same.

5. The three-dimensional display panel according to claim 1,
wherein the three-dimensional display panel comprises a plurality of light controllers,
wherein a light controller is provided on each subpixel of each pixel unit, and
wherein each light controller is configured to control a direction of light emitted through each subpixel, so that lights emitted through different subpixels of the pixel unit are directed to follow different optical paths.

6. The three-dimensional display panel according to claim 1, further comprising a plurality of light controllers arranged in an array,
wherein a light controller is provided on each pixel unit and covers the at least two subpixels of the pixel unit, and
wherein the light controller is configured to direct lights passing through different regions of the lens to follow different optical paths.

7. The three-dimensional display panel according to claim 6, wherein each light controller is a free-form lens.

8. The three-dimensional display panel according to claim 1, further comprising a plurality of light controllers arranged in an array,
wherein a light controller is provided on each pixel unit and covers the at least two subpixels of the pixel unit, and
wherein each light controller is configured to direct lights emitted through different subpixels of the pixel unit to follow the same optical path.

9. The three-dimensional display panel according to claim 1,
wherein the three-dimensional display panel comprises a plurality of light controllers, and
wherein each light controller covers a group of adjacent pixel units, and is configured to direct lights emitted by different pixel units in the group of adjacent pixel units to follow different optical paths.

10. The three-dimensional display panel according to claim 9, wherein each light controller is a free-form lens.

11. The three-dimensional display panel according to claim 1,
wherein the three-dimensional display panel is a liquid crystal three-dimensional display panel,
wherein the three-dimensional display panel further comprises a black matrix on the plurality of pixel units, and
wherein the black matrix comprises a plurality of openings that correspond to the at least two subpixels of each of the plurality of pixel units.

12. The three-dimensional display panel according to claim 1,
wherein the three-dimensional display panel is an organic light-emitting diode three-dimensional display panel,
wherein the three-dimensional display panel further comprises a pixel defining layer on the plurality of pixel units, and
wherein the pixel defining layer comprises a plurality of openings that correspond to the at least two subpixels of each of the plurality of pixel units.

13. A display device comprising the three-dimensional display panel according to claim 1.
